(19) United States
(12) Patent Application Publication
(10) Pub. No.: US 2022/0319949 A1
(43) Pub. Date: Oct. 6, 2022

(54) Heat transfer system and electric or optical component

(71) Applicant: Thermal Channel Technologies Oy, Oulu (FI)

(72) Inventors: Vesa Pentikäinen, Espoo (FI); Kimmo Jokelainen, Espoo (FI)

(21) Appl. No.: 17/609,803

(22) PCT Filed: May 6, 2020
(86) PCT No.: PCT/FI2020/050305

§ 371 Date: Nov. 9, 2021

(30) Foreign Application Priority Data
May 10, 2019 (FI) 20195390

(51) Int. Cl. H01L 23/367; H01L 23/427; H01L 23/40

(52) U.S. Cl. CPC H01L 23/3672; H01L 23/427; H01L 23/4006

(57) ABSTRACT

A novel heat transfer system is herein proposed involving a coupler which, when attached to a heat sink, defines at least a part of a vapor chamber inside the heat transfer system. The coupler attaches component heat source to the header to a thermally transferring connection with the heat sink.

### FIELD

The present disclosure relates to the cooling of heat sources, such as electric or optical components.

### BACKGROUND

The cooling of electric components, such as microprocessors, LEDs, IGBT modules, etc., is conventionally based on attaching a heat transfer element to physical and thermally conducting connection to the component. A typical such heat transfer element comprises a heat sink that provides for a large heat dissipation area for dissipating heat away from the component to the ambient. Also, liquid cooled heat transfer elements are known, such as radiators.

There is also known to provide a heat sink with inner cavities so as to device a heat pipe inside the heat sink for facilitating efficient heat distribution across the heat sink. CN 103307579 B discloses such a solution.

WO 2009/108192 A1 discloses an improvement to heat sinks with heat pipes. WO 2009/108192 A1 discloses a heat sink with a bottom vapor chamber leading to a heat pipe which, in turn, provides heat to a stack of heat dissipating plates.

There remains, however, the need to further develop the cooling of electric components without excessively increasing the complexity of the heat transfer system or at least to provide the public with a useful alternative.

### SUMMARY

A novel heat transfer system is herein proposed involving a coupler which, when attached to a heat sink, defines at least a part of a vapor chamber inside the heat transfer system. The vapor chamber may be between the coupler and a header of the heat sink, for example. The coupler attaches a heat source, such as that comprised by an electric or optical component or system, to the header to a thermally conducting transferring with the heat sink. The heat sink also has at least one heat pipe which is integrated thereto and which is in fluid communication with the vapour chamber for improving effective heat transfer between the coupler and the dissipation section.

Further, it is herein proposed an electric or optical component formed on a coupler, which forms a vapor chamber with the heat sink, wherein a heat source of the electric or optical component is directly or indirectly bonded or soldered to the base of the coupler.

The invention is defined by the features of the independent claims. Some specific embodiments are defined in the dependent claims.

Considerable benefits are gained with aid of the present proposition. Because a vapor chamber is formed inside the heat transfer system, preferably between the coupler and heat sink, an effective transfer, distribution, and dissipation is achieved with a very simple construction which is susceptible for mass production, e.g. by extrusion.

According to an embodiment the element to be cooled is integrated to the coupler thus omitting at least one interference from the heat transfer line between the heat source and dissipation section of the heat sink, thus leading to more improved effectiveness.

### BRIEF DESCRIPTION OF THE DRAWINGS

In the following certain exemplary embodiments are described in greater detail with reference to the accompanying drawings, in which:

FIG. 1 illustrates a partly sectioned perspective view of a heat transfer element in accordance with at least some embodiments;

FIG. 2 illustrates a perspective view of a heat transfer element in accordance with at least some embodiments with a coupler being configured to carry an electric component;

FIG. 3 illustrates a sectioned side view of a heat transfer element in accordance with at least some embodiments;

FIG. 4 illustrates a sectioned side view of a heat transfer element in accordance with at least some embodiments;

FIG. 5 illustrates a sectioned side view of a heat transfer element in accordance with at least some embodiments;

FIG. 6 illustrates a partially sectioned perspective view of a coupler with integrated electronics in accordance with at least some embodiments;

FIG. 7 illustrates a partially sectioned perspective explosion view of a heat transfer element in accordance with at least some embodiments employing a separate header;

FIG. 8 illustrates a partially sectioned perspective explosion view of heat transfer element in accordance with at least some embodiments employing a separate header and heat pipe, and

FIG. 9 illustrates a partially sectioned perspective explosion view of heat transfer element in accordance with at least some embodiments employing an integrated header and coupler.

### EMBODIMENTS

In the present context a “dissipation section” refers to an element or part of the heat sink that comprises more heat dissipation surface area than a solid object having the same external dimensions. For example, the dissipation section may comprise a plurality of fins that increase the dissipation surface area compared to, for example, a prismatic block having the same external dimensions.

In the present context “integrated” refers to an element or feature that is an integral part of another element or feature such that said elements or features are unseparable.

In the present context the expression “directly or indirectly bonded” refers to bonding, wherein an element is bonded to another element such that the bonding surfaces of the elements engage each other directly there is a bonding coating there between, such as a metal membrane, particularly a copper membrane.

In the present context the expression thermally conducting connection or material refers to a connection or material, in which the majority of the heat flux flowing through a given surface is transferred through conduction as opposed to radiation or convection, for example.

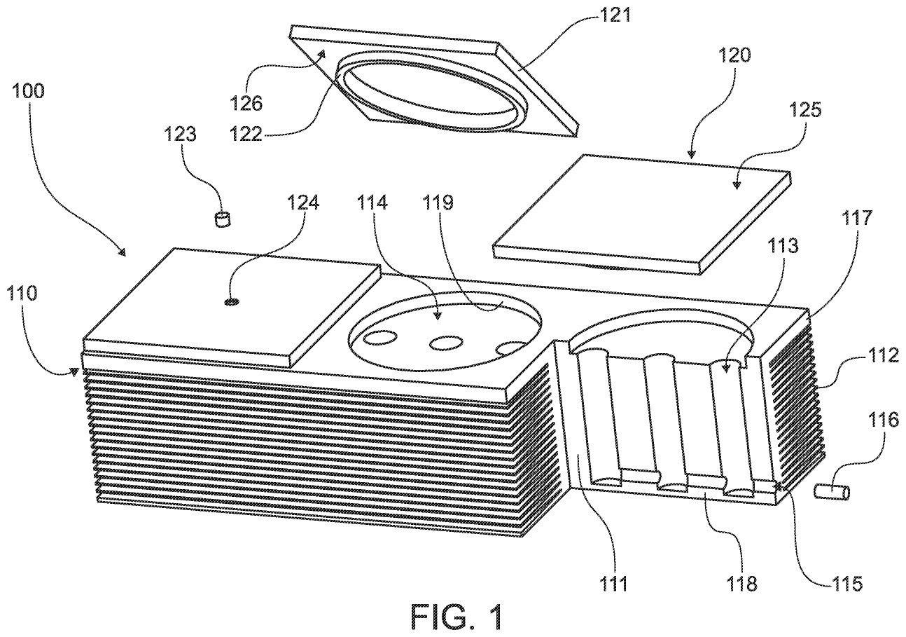

FIG. 1 shows an exemplary heat transfer system 100 for transferring heat from a heat source to the ambient air. It should be understood that the system 100 is presented in FIG. 1 in a reversed orientation to the intended orientation of use. In other words, the top part of the system 100 of FIG. 1 would be the below the bottom part in an operational state, wherein the return flow of the liquid phase of the heat transfer fluid contained inside the heat sink would benefit from or be provided for by gravitation. The system 100 has two major components, namely a heat sink 110 and a coupler 120 which is used to couple the heat source to the heat sink 110. The coupler 120 is specifically designed achieve two forms of connection. The coupler 120 brings the heat source not only in physical connection with the heat sink 110 but also in a thermally transferring connection so as to transfer heat away from the heat source. The embodiment shown in FIG. 1 three such couplers 120 to accommodate three heat sources. Naturally, the heat sink 110 can be modified to include only one, two, or a larger plurality of couplers 120 by varying the construction. The heat sink 110 may include only one bank as shown in FIG. 1 or several banks connected to each other (not illustrated). Also, several heat sources may be attached to a single coupler, e.g. a matrix of high power LED components.

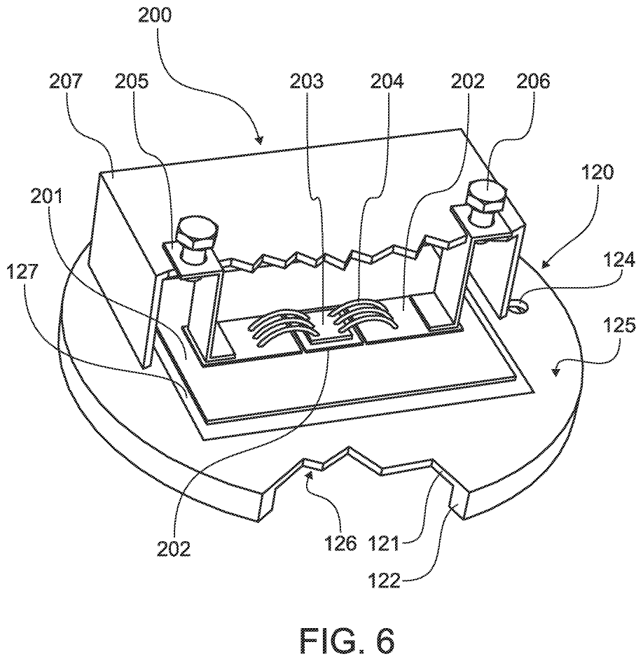

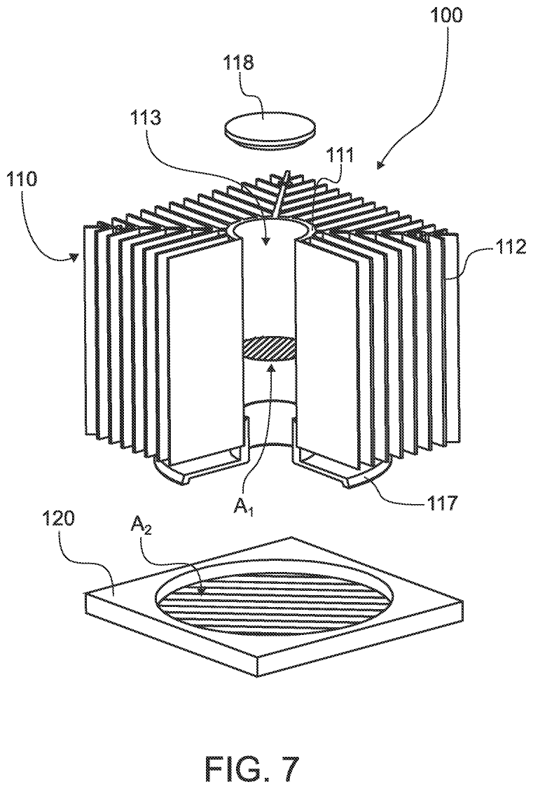

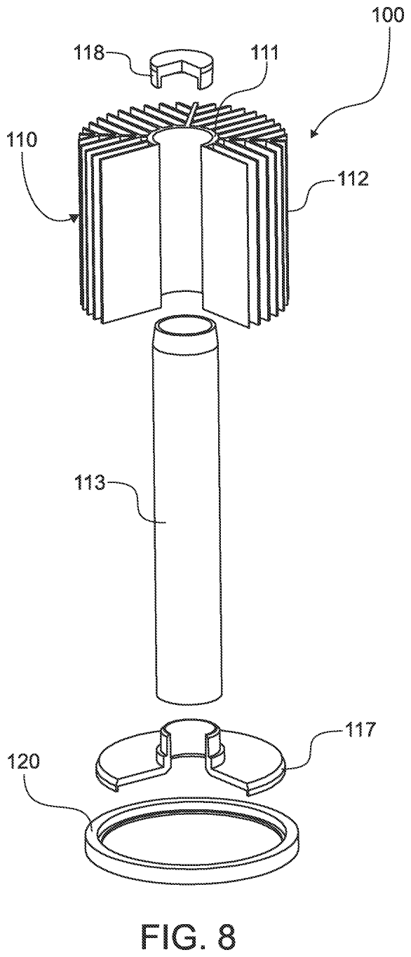

The heat sink 110 is preferably made from a thermally conducting material, such as aluminium or an aluminium alloy. The heat sink 110 may be produced by extrusion which provides the basic shape of the heat sink 110 and may be adapted to produce heat sinks 110 of different sizes to accommodate a variable number of heat sources. The heat sink 110 features a body 111 and a dissipation section 112 which extends from the body 111. The dissipation section 112 includes elements which increase the heat dissipating surface area compared to a solid block, such as a prismatic block. In the example of FIG. 1 the dissipation section 112 takes the form of a rather traditional set of heat dissipating fins, which extend from the body 111 in opposite directions. The dissipation section 112 is integrated to the body 111. The integration may be achieved by manufacturing the dissipation section 112 and the body 111 in the same additive manufacturing stage, e.g. by extrusion. The body 111 itself extends between a header 117 and an end 118, i.e. two end plates, and defines the height of the heat sink 110 in a first dimension. The header 117 acts as a receiver of the heat source or sources through the coupler 120. The header 117 may be an integral part of or a separate part (FIGS. 7 and 8) attached to the rest of the heat sink 110. It therefore follows that the coupler may be an integral part of the header which, in turn, may be attached to the dissipation section (not illustrated). To receive the coupler 120, the header 117 may have a cooperating shape which facilitates an interference fit, a thread, a bayonet mount, a cone surface, or a comparable attachment mechanism. Alternatively, the header may include features to receive the coupler 120 through an adaptor (not illustrated), such as a threaded sleeve, collar, etc. As will become apparent hereafter, the header 117 forms part of a vapor chamber. The heat sink may include several headers. For example, a modification of the embodiment of FIG. 1 would include a second set of headers (not illustrated) at the end 118 opposing the shown headers 117. It is also possible to include headers of different construction. For example, one header or set of headers could feature a female cavity for forming part of a vapor chamber, whereas another header or set of headers could feature a planar surface for forming part of a vapor chamber. In addition or alternatively, one header or set of headers could form part of the enclosure of the heat source (cf. embodiment shown in FIG. 6).

Vapor chamber 130 has a width in a first Cartesian dimension and a height in a second Cartesian dimension. The width is, at least according to some embodiments, considerably larger than the height making the vapor chamber 130 generally flat. The purpose of the flat shape is to distribute the heat across the first dimension. Such an effect is particularly useful in spread heat from a point source to a wide surface area or to a large volume. The vapor chamber 130 has an enclosed volume, in which a heat transferring fluid is arranged to act. The heat transferring fluid is preferably a saturated steam with little or no impurities. The vapor chamber may include a support structure, such as a net, (not illustrated) to prevent the chamber from collapsing.

The dissipation section 112 extends in a transversal dimension in respect to the body 111 and defines the width of the heat sink 110 in a second dimension. The body 111 runs along the heat sink 110 along the third Cartesian dimension thus defining the length of the heat sink 110. As may be concluded, the heat sink 110 is preferably extruded in the third dimension. Naturally, also other additive manufacturing techniques, such as 3D printing, casting, sintering, etc., are foreseeable. In addition, several machining techniques are foreseen, particularly skiving from a block to produce a large quantity of dissipating strips that are attached to the body (not illustrated).

The heat sink 110 includes cavities which improve the thermal efficiency of the heat transfer system 100. Firstly, the body 111 features at least one, i.e. one or more, heat pipe(s) 113. The heat pipe or heat pipes 113 is/are at least partially enclosed by the body 111. In the shown example the heat sink 110 includes nine heat pipes 113 arranged in three groups, one group per heat source. According to the embodiments illustrated in FIGS. 1 to 5 heat pipe 113 is integrated to the body, i.e. the heat pipe is an integral part of the body 111. This means that the heat pipe 113 cannot be separated from the body 111. In the illustrated example the heat pipe 113 is formed as a cavity (Ger. Ausnehmung) in the basic material of the heat sink 110. The integration of the heat pipe 113 to the body 111 is achieved by boring out the channel into the body 111 after extrusion of the heat sink 110. Alternatively, the heat pipe could be produced during extrusion or casting by arranging the heat pipe to extend in the third dimension (not illustrated).

Referring to the dimensions of the vapor chamber 130 discussed above, the heat pipe 113 also has a width or an average width in the first Cartesian dimension and a height in a second Cartesian dimension. The width is, at least according to some embodiments, considerable smaller than the height making the heat pipe 113 generally tall and narrow. The purpose of the tall shape is to transfer heat across the second dimension for a considerable distance to as to enable a sufficient opportunity for the dissipation section 112 to dissipate the heat. The cross-section of the heat pipe 113 may be circular or any suitable shape. The heat pipe 113 may diverge from or converge with another heat pipe and/or to connect to more than one vapor chamber. The heat pipe 113 has an enclosed volume, in which a heat transferring fluid is arranged to act. The heat transferring fluid is preferably a saturated steam with little or no impurities.

Compared to one another, the vapor chamber 130 and the heat pipe 113 may have different cross-sectional areas. For example, the cross-sectional area Az of the vapor chamber 130 may be larger than the cross-sectional area A₁ of the heat pipe 113, when the cross-section is taken against the dimension of the greatest extension of the heat pipe 113 (highlighted in FIG. 7). For example, the cross-sectional area A₂ covered by the vapor chamber 130 may be twice or more of the cross-sectional area A₁ of the heat pipe 113, particularly three to five times of that of the heat pipe 113. In particular, if there are several heat pipes connected to the vapor chamber, the disproportionality applies to the combined cross-sectional area of the heat pipes. Even larger disproportions are foreseen. Ratios between the cross-sectional area A₁ of the heat pipe(s) 113 to the cross-sectional area Az of the vapor chamber 130 may be between 1 to 25 or 1 to 100 or even more disproportionate. Accordingly, the role of the vapor chamber 130 in spreading the heat and the role of the heat pipe 113 for transferring the heat for dissipation is emphasized. The coupler 120 and particularly a matching header 117, such as that disclosed in connection with FIGS. 1 to 8, is very beneficial in providing such large surface area for the vapor chamber 130. The disproportion will efficiently facilitate vaporization at the vapor chamber, particularly along a generally planar vaporization zone, and condensation along the heat pipe 113, particularly along a dimension extending from the generally planar vaporization zone.

The heat pipe 113 extends from the header 117 towards the end of the heat sink 110. According to the illustrated embodiments the heat pipe 113 is a blind cavity. However, also through cavities are possible, which would require a closing mechanism (not illustrated) for closing the end of the heat pipe 113. In the illustrated embodiments the heat pipes 113 are joined adjacent the end 118 of the heat sink 110 by a channel 115. The channel 115 may bring only the heat pipe 113 in fluid communication or it may, as illustrated, provide an outlet to the ambient. The channel 115 may then serve as a port for filling the internal volume of the heat sink 110 with heat transfer fluid and/or for bleeding the system and/or providing an under pressure to the heat transfer fluid in the internal volume of the heat sink 110. In the present context under pressure is in relation to the ambient pressure outside the heat sink. Alternatively, the pressure of the heat transfer fluid may be optimized by a vacuum pump so as to bring the fluid to the boiling point, whereby the vapor of the boiling fluid will exert impurities from the system. As a result the internal volume of the heat sink will contain only or mostly the heat transfer fluid in steam and liquid phases and minimally or no impurities. The resulting pressure of the heat transfer fluid will then vary according to the temperature of the system and to saturated steam pressure of the fluid. The channel 115 may be closed with a plug 116 which may itself be constructed as a valve for accommodating the filling, bleeding, and/or pressurizing of the internal volume of the heat sink 110. The plug 116 and the receptive section of the channel 115 may be cylindrical, conical, or spherical for a good fit. The sealing of the plug 116 may be secured by using additional welding, friction welding, soldering, epoxy coating, anodizing, or any other suitable method known in the art.

Additionally or alternatively, the base 121 of the coupler 120 may be provided with an opening 124 and plug 123 for a similar purpose. It therefore follows that the system 100 may be filled, bled, and pressurized through a single opening.

The illustrated embodiments feature heat pipes 113 that are generally cylindrical in shape. The construction, number, and shape of the heat pipes 113 may, however, be varied. For example, the heat pipes 113 may extend in parallel to each other, as shown, or they may be offset from one another. The heat pipes 113 may have a straight orientation, as shown, or they may be slanted, curved, spiral, or any other shape. The respective orientations of the heat pipes may be adjusted to promote gravitational return flow of the heat transfer fluid in the liquid phase. The cross-sectional shape of the heat pipes may be selected to promote gaseous flow of the heat transfer fluid so as to avoid excess collision of streams in different phases, i.e. gas and liquid flows, and/or cavitation. Also, the heat pipes may be separate or joined at the end or at any point along their extension.

The performance of the heat pipe 113 may be further improved providing a wick (not illustrated) to the surface of the heat pipe 113. The wick may be provided before installing the coupler 120 by installing and/or applying a woven fibre, spray, or other suitable coating, lining, or piece, such as a sleeve, onto the surface of the heat pipe 113. In particular, the wick may be produced by applying a sintered metal or ceramic foam or porous granules to the heat pipe. The wick may be a porous layer or form made of ceramic or carbon based or other suitable materials. Such wick coatings are widely available to lead liquid by capillary action from the condensing zone to an evaporation zone, even against gravitation.

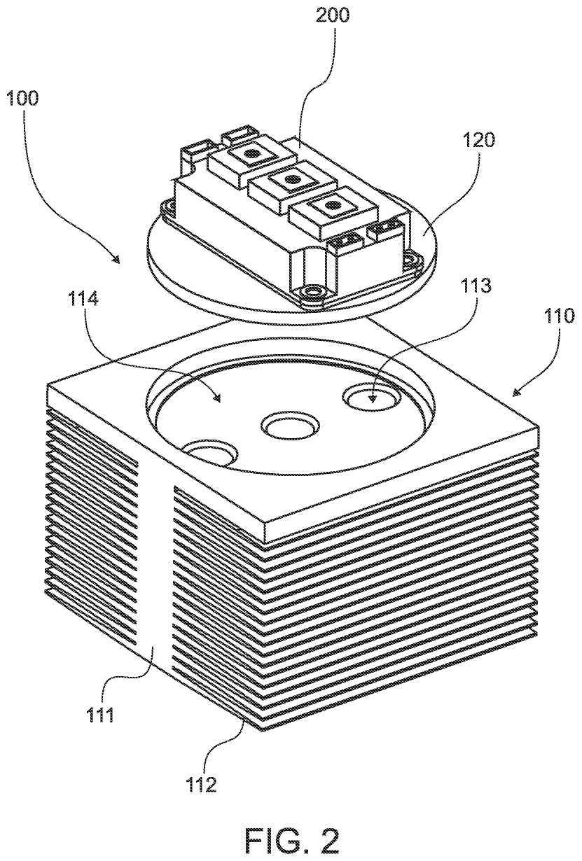

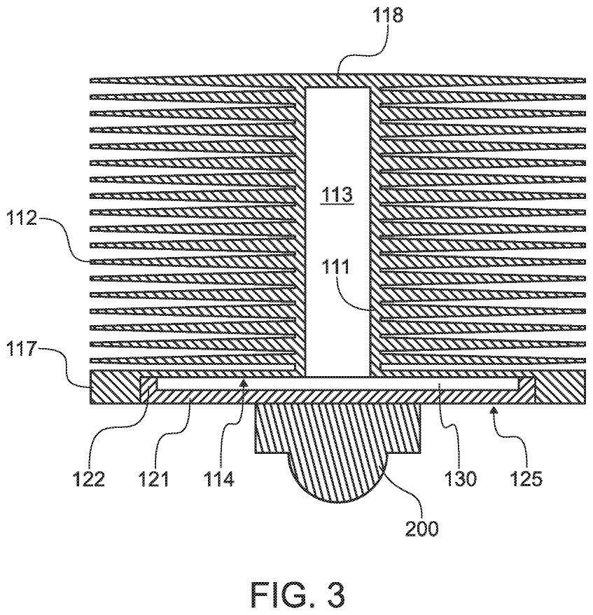

The header 117 of the heat sink 110 is intended to receive the heat source which is to be cooled. The element may be an electric component, such as a processor, an IGBT module, or a transformer, or an optical component, such as an LED, a reflector of a laser system. Other examples of such an element include alternating current bridges, voltage regulators, fuel cells, batteries or battery cells, motor parts, particularly the coil of a stator, power amplifier components, etc. The heat source may alternatively be a chemical, biochemical, or electrochemical component or process, such as a battery. The regardless of the type of the heat source, the element to be cooled is attached to the header 117 with a coupler 120. According to the embodiment shown in FIG. 1, the heat transfer system 100 is constructed to receive three such elements in-line through three couplers 120. FIG. 1 shows the coupler 120 in a simple plate-like construction. The coupler 120 includes a base 121 which acts as a recipient of the heat source on a first surface 125 and as a closing element on the opposing second surface 126. The second surface 126 has a sealing element 122 which is designed to contact the header 117 such that the heat transfer liquid contained in the inner volume of the heat sink 110 is contained therein. The connection between the coupler 120 and the header is discussed in greater detail here after with reference to FIGS. 3 to 5. The connection between the coupler 120 and the heat source is discussed in greater detail here after with reference to FIGS. 2 and 6.

FIG. 1 also reveals the exemplary construction of a vapor chamber which is formed between the header 117 and the coupler 120, when the latter is attached to the former. The header 117 and the coupler 120 are designed that an inner volume is formed there between to act as a vapor chamber 130. The basic idea is to arrange the heat source as close to the vapor chamber 130 as possible. As will transpire here after, the heat source is separated from the vapor chamber 130 with minimal material thickness. In the example shown in FIGS. 1 and 3, the header 117 is recessed, whereby a surface 114 is retracted from the basic end surface of the header 117. The recessed surface 114, which is referred to as a counterpart surface, may have a circular shape. The counterpart surface 114 is connected to the basic end surface of the header 117 by a peripheral wall 119. The sealing member 122 of the coupler 120 is fittingly shaped so as to fit inside the peripheral wall 119 and to seal against the peripheral wall 119 and the counterpart surface 114. In other words, the sealing member 122 forms the male counterpart of the connection between the coupler 120 and the header 117, whereas the recess, formed by the counterpart surface 114 and the peripheral wall 119, forms the female counterpart. The physical connection between the coupler 120 and the header 117 may be an interference fit, particularly a shrink fit, wherein the header 117 is first heated, then the coupler 120 installed, whereby the cooling and shrinking header 117 forms a tight connection. The connection may alternatively or additionally comprise threads (not illustrated) between the sealing member 122 and the peripheral wall 119. Additionally or alternatively, the connection between the coupler 120 and the header 117 may be facilitated through a keyway, wedge key, welding, adhesives, or any known attachment method generally known in the field.

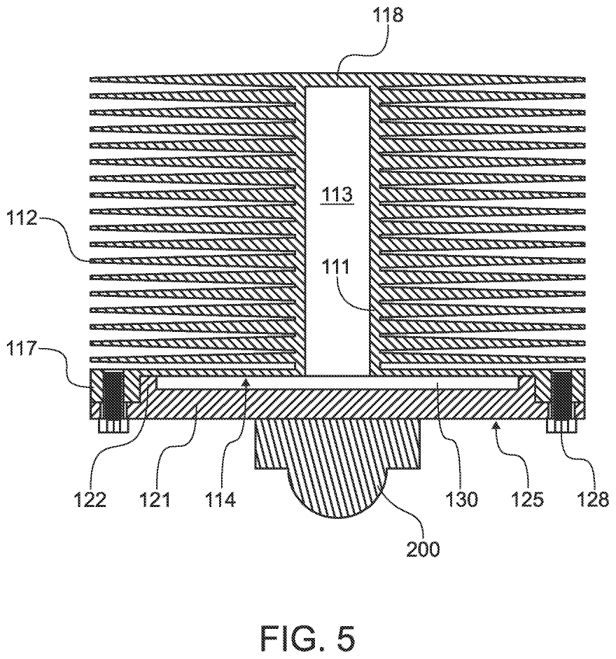

FIG. 5 shows a modification of the embodiment of FIG. 3, where the coupler 120 comprises additional optional screws ensuring the connection with a flange of the coupler 120 and the receptive threaded bores in the header 117. Alternative form fitting affixers, such as bolts and protruding threaded shafts, clamps, snap locks, lock pins, etc., are foreseen but not illustrated.

FIG. 2 shows an optional groove on the counterpart surface 114 adjacent to the peripheral wall 119 for receiving the end of the sealing member 122 and thus ensuring a good fit there between. The groove also ensures sufficient installation depth of the coupler 120 and/or that the vapor chamber has an appropriate height.

As shown in FIGS. 1 and 3, the vapor chamber 130 is defined by the counterpart surface 114, the sealing member 122 and the second surface 126 of the coupler 120. The counterpart surface 114 and the second surface 126 of the coupler 120 define the ends of the vapor chamber 130, whereas the sealing member 122 defines the cross-sectional shape of the vapor chamber 130. These surfaces may be generally flat to induce vaporization of the heat transfer fluid. As may also be seen from FIGS. 1 and 3, the vapor chamber 130 is in fluid communication with the heat pipe 113. In embodiments, where there are several heat pipes 113, such as in FIG. 1, the vapor chamber 130 preferably connects the heat pipes 113 to each other, particularly in a transversal orientation in respect to the orientation of the heat pipes 113. Thus, the vapor chamber 130 is very effective in spreading the heat across the heat pipes 113.

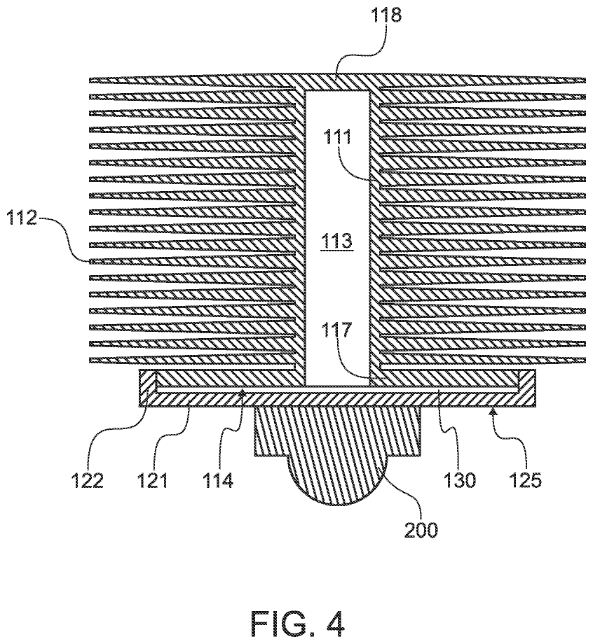

FIG. 4 shows a reversed connection between the coupler 120 and the header 117, wherein the header 117 forms the male counterpart and the coupler 120 forms the female counter part of the connection. Accordingly, the header 117 is planar as opposed to recessed (cf. FIGS. 1 and 2). The end surface of the header 117 therefore forms the counterpart surface 114 forming one end surface of the vapor chamber 130. According to the embodiment of FIG. 4, the sealing member 122 is constructed to receive the header 117 such to form the vapor chamber 130 there between. Accordingly, the interference fit, such as a forced fit, is achieved by first heating and thus expanding the coupler 120, then installing it to the header 117, and finally allowing the coupler 120 to cool and retract to form a tight fit there between.

It is to be noted that is all illustrated embodiments, the sealing element 122 has a peripheral closed profile which defines the cross-sectional shape of the vapor chamber 130 an end of the vapor chamber 130. In the illustrated embodiments the sealing member 122 is illustrated as cylindrical, but other shapes are foreseen. While a cylindrical shape is preferred, also otherwise curved shapes are preferred over straight angles for sealing purposes. Indeed, the sealing member 122 may be conical, grooved, or otherwise shaped to achieve a good sealing. In other words, the sealing element is preferably rotationally symmetrical. The fit between the sealing member 122 and the header 117 may be further improved by additional seals (not illustrated) there between. Such additional seals include O-rings, washers, particularly copper alloy washers, foils, sealing agents to increase flexibility between the parts and to compensate possible thermal expansion mismatch and forces between the parts. Such additional seals also serve the purpose of levelling out imperfections, such scratches, grooves, etc., in the engaging surfaces.

The vapor chamber 130 forms a first fluid cooling volume and the heat pipe 113 or heat pipes together form a second fluid cooling volume inside the heat sink 110. The purpose of the fluid cooling volumes is to absorb heat that is conducted through the coupler through a phase transformation at a vaporization zone in the first fluid cooling volume and condensing zones in the second fluid cooling volume(s). A vaporization zone is formed on the second surface 126 of the coupler 120 (FIGS. 1 and 6). A condensing zone or zones is formed on the surface of the heat pipe 113. The first and second fluid cooling volumes form the inner volume of the heat sink 110. As mentioned above, the inner volume of the heat sink 110 is filled with a heat transfer fluid, the purpose of which is to effectively transfer the heat from the second surface 126 of the base 121 of the coupler 120 to the heat dissipation section 112. The heat transfer fluid may be any fluid known in the field for this purpose that does not deteriorate the material of the heat sink 110. The selection of the fluid is influenced by pressure inside the inner volume of the heat sink. The fluid used in the system is selected such that the boiling point of the fluid corresponds to the inner pressure of the inner volume of the system. Practically speaking, the boiling point may be affected by imperfections, such as small quantities of air or contaminants, in the heat transfer fluid. In addition, the heat transfer properties, viscosity, saturated vapor pressure, physical molecular weight, compatibility with the heat sink material, chemical reactivity, and/or other physical properties may be factored in the selection of the heat transfer fluid. The internal pressure of the heat sink at a given moment is the result of the heat transfer fluid selected and the temperature of the system. For example, acetone may be used for a heat sink made of aluminium or an aluminium alloy. The heat transfer fluid is preferably added and then pressurized to an under pressure in respect to ambient pressure at room temperature (20 degrees Celsius). A suitable exemplary pressure range is 0.1 to 3 or 4 bar for a system which is operational in room temperature and has a maximum temperature of, e.g., 100 degrees Celsius or more, particularly 100 degrees Celsius at 3.6 bar or 90 degrees Celsius at 2.7 bar. The behavior of heat transfer fluids used in heat pipes is well known. It may, however, be pointed out that compared to regular circulating liquids the heat transfer fluid used in the present context is characterized by exhibiting a saturated vapor and liquid phase simultaneously across the inner volume of the heat sink.

The element to be cooled may be attached to the coupler 120 as a separate component or it may be integrated to the coupler 120. The former option is described in connection with FIG. 2, the latter in connection with FIG. 6. In both alternatives the coupler 120 is preferably set to attach the element to be cooled to the heat sink 110 directly without an adapter.

FIG. 2 shows an embodiment of an IGBT module 200 attached to the coupler 120 as the element to be cooled. The exemplary IGBT module could alternatively be any other electric component, such as a circuit board, having its own housing or an optical component, such a surface treated with a substance having optically reflective or absorptive properties. An example of such an optical component is a layer of phosphorous compound used to absorb coherent light, such as a laser beam, or high intensity light and to emit light in a particular frequency band. Such layers are prone to generate significant amounts of heat that, if not dissipated, may deteriorate the layer. The exemplary IGBT module 200 is attached to the first surface 125 of the base 121 of the coupler 120 through screws, rivets, or similar affixers. A layer of thermal interface material is preferably applied on the first surface 125. The thermal interface material may be applied as a paste, tape, a covering sheet, or any other applicable method. It is noteworthy to point out that the connection between the IGBT module 200 and the base 121 is not only physical but also thermally conducting so as to transfer heat as effectively as possible from inside the IGBT module 200 to the vapor chamber 130 through the base 121. Such an attachment of an electrical or optical component to a planar cooling construction is known per se.

FIG. 6 shows an embodiment of an electric component 200, such as a semiconductor chip or a processing core, integrated to the coupler 120. The coupler 120 itself is similar to that described in connection with FIGS. 2 to 4. To achieve outstanding heat conducting properties in the connection between the heat source 203 and the second surface 126 of the coupler 120, the bottom of conventional encased electrical components has been omitted and the bonding features have been produced directly onto the base 121 of the coupler 120. In addition, the coupler 120 is preferably made of a heat conducting material, such as copper, aluminium, aluminium alloy, aluminium oxide, or any other applicable material. The surface of the material may be further treated by/with anodization, painting, thermal spraying, plasma, nanomaterial, or comparable enhancing coatings or treatments.

Firstly, a coating 127 has been provided to the first surface 125 of the base 122 to enable bonding of an electric heat source 203 to the base 121. The coating 127 may be for example a copper coating which may be provided by explosion welding. Other materials enabling bonding, particularly galvanic bonding, or soldering are foreseen. Alternatively, the base 121 itself or the first surface thereof may be constructed from a material that enables bonding or soldering of electric components. On top of the optional coating 127 there is a substrate 201 which is conventionally part of the separate component. The substrate 201 may be a DBC/AMB substrate which provides sufficient heat resistance and conductivity with sufficient electrical insulation. Examples of such substrates include alumina (Al₂O₃), LTCC (low temperature co-fired ceramic) or any other material generally known in the field. Semiconductor elements are formed on the substrate 201. In the illustrated example the heat source 203, i.e. a processor or other chip, is bonded on the substrate 201. It is preferred that the heat source 203 is bonded to the substrate through a metal connection. Alternatively, the heat source 203 may be bonded directly on the coating 127 or on the first surface 125 of the base 121. The substrate 201 also houses conductors 202 which are connected to the heat source 203 by leads 204. The conductors 202 are, in turn, connected to the outside of the electric component 200 through terminals 205 that penetrate the cover 207. The cover 207 is attached to the terminals 205 by affixers 206, e.g. screws, that also attach external leads to the terminals 205.

Let us now turn to the embodiments shown in FIGS. 7 and 8 proposing a non-integral header 117.

According to the embodiment of FIG. 7 the header 117 is a separate part in respect to the dissipation section 112 of the heat sink 110. The body 111 of the heat sink 110 may be a tubular body part from which the dissipation section 112 extends and to which the similarly tubular collar of the header 117 may be installed. The body 111 forms the heat pipe 113. The end 118 of the heat pipe 113 may be closed with a separate plug (as illustrated) or the body 111 may comprise an integral end plate (not illustrated). The header 117 is a non-integral piece that may be attached to the heat sink 110 through an interference fit, affixers, etc. The header 117 may take the form of a disc that is shaped to engage the body 111 of the heat sink 110 on the one hand and the coupler 120 on the other hand so as to enclose at least part of the vapor chamber that forms between the header 117 and the coupler 120. The coupler 120 may form the female (as illustrated) or male (not illustrated) counterpart in forming the vapor chamber with the header 117. The coupler 120 may be constructed to receive a separate enclosed heat source as in the embodiments of FIGS. 1 to 5 or it may accommodate the integrated heat source as in the embodiment of FIG. 6.

The embodiment of FIG. 8 is a modification of the embodiment of FIG. 7 in that not only is the header 117 a separate piece (although it need not be), the heat pipe 113 is non-integral as well. The heat pipe 113 may be formed of a separate pipe that is attached to the body 111 of the heat sink 110. The attachment may be an interference fit, such as a shrink-fit. The end 118 of the heat pipe 113 may be closed with a separate plug (as illustrated) or the body 111 may comprise an integral end plate (not illustrated). The heat pipe 113 may on the other hand be attached to the header 117 by attaching the pipe to the collar of the header 117. Similarly, the attachment may be an interference fit, such as a shrink-fit. As illustrated, the heat pipe 113 may be constructed as longer than the body 111 of the heat sink 110 so as to maximize the effect of the heat pipe 113 or to transfer heat further from the heat source for dissipation.

The embodiments of FIGS. 7 and 8 could be modified by replacing the separate header 117 and coupler 120 with a single integrated unit (not illustrated) which could be formed by casting or any additive manufacturing method or by first boring out the vapor chamber and then plugging the bore to seal the chamber. Alternatively, the header 117 could be a simple collared disc that could be received by an appropriately designed coupler 120 to act as the female counterpart as in the embodiment of FIG. 4.

In the embodiments described above the coupler 120 attaches the heat source 203 to the header 117 into a thermally transferring connection with the heat sink 110. While the purpose of the system 100 is to cool the heat source 203, the act of cooling employs several modes of heat transfer. First, the heat is transferred from the heat source to the coupler 120 by means of conduction or mostly conduction. The heat therefore conducts through the attachment between the heat source and the coupler, the attachment including for example adhesives, a circuit board, heat paste, solder, etc. Next, the heat transfer further by means of conduction from the coupler 120 to the heat transfer fluid occupying the vapor chamber 130. In the vapor chamber, the heat increases the temperature of the heat transfer fluid to the boiling point. At this stage heat is absorbed by the phase transition from fluid to vapor. Next, the heat is transferred through convection to a cooler section of the heat sink 110 along the heat pipe 113. At this stage the heat transfer fluid is condensated onto the surface of the heat pipe 113, wherein the phase transition from vapor to fluid absorbs energy as heat in the dissipation section 112. The heated dissipation section 112 will, in turn, conduct the heat to the dissipation surface area which dissipates the heat to the environment mostly through conduction and radiation. The described path of heat transfer is particularly efficient due to the relatively small number of heat transfer interfaces, especially if the heat source is integrated to the coupler, and the lack of energy consuming devices for circulating coolants, etc.

It is to be understood that the embodiments of the invention disclosed are not limited to the particular structures, process steps, or materials disclosed herein, but are extended to equivalents thereof as would be recognized by those ordinarily skilled in the relevant arts. It should also be understood that terminology employed herein is used for the purpose of describing particular embodiments only and is not intended to be limiting. Indeed the skilled person may foresee several avenues of further developing the basic principles herein described and as defined by the independent claims.

For example, the effectiveness of the heat transfer system may be further improved by installing fans or other forms of air injection to the end of the dissipation section so as to blow the warm or hot air off the heat dissipating section.

Also, a cooling liquid circulation is also possible to add to the system, such as to the end of the heat sink. Accordingly, the heat transfer fluid may be cooled in a separate radiator.

The end 118 of the heat sink 110 may feature another vapor chamber, such as that provided by the coupler 120. In other words, the heat pipe 113 or heat pipes 113 may be closed from both ends by a coupler 120, whereby one or both may feature a heat source to the cooled.

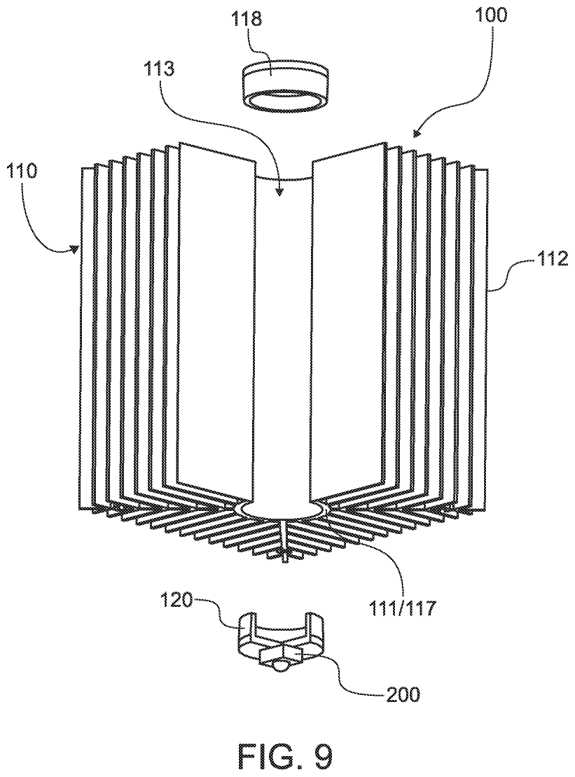

Yet another embodiment is shown in FIG. 9, wherein the body 111 acts as the header 117 for receiving the coupler 120 that carries the component 200 which is to be cooled. The coupler 120 encloses a vapor chamber inside the heat transfer system 100, particularly inside the heat sink 110. In this embodiment the vapor chamber is therefore not formed between the coupler 120 and the header 117 but as a continuum of the heat pipe 113 formed by the body 111 of the heat sink 110. Connection of the coupler 120 to the heat sink 110 may constructed as described above.

Reference throughout this specification to “one embodiment” or “an embodiment” means that a particular feature, structure, or characteristic described in connection with the embodiment is included in at least one embodiment of the present invention. Thus, appearances of the phrases “in one embodiment” or “in an embodiment” in various places throughout this specification are not necessarily all referring to the same embodiment.

As used herein, a plurality of items, structural elements, compositional elements, and/or materials may be presented in a common list for convenience. However, these lists should be construed as though each member of the list is individually identified as a separate and unique member. Thus, no individual member of such list should be construed as a de facto equivalent of any other member of the same list solely based on their presentation in a common group without indications to the contrary. In addition, various embodiments and example of the present invention may be referred to herein along with alternatives for the various components thereof. It is understood that such embodiments, examples, and alternatives are not to be construed as de facto equivalents of one another, but are to be considered as separate and autonomous representations of the present invention.

Furthermore, the described features, structures, or characteristics may be combined in any suitable manner in one or more embodiments. In the following description, numerous specific details are provided, such as examples of lengths, widths, shapes, etc., to provide a thorough understanding of embodiments of the invention. One skilled in the relevant art will recognize, however, that the invention can be practiced without one or more of the specific details, or with other methods, components, materials, etc. In other instances, well-known structures, materials, or operations are not shown or described in detail to avoid obscuring aspects of the invention.

While the forgoing examples are illustrative of the principles of the present invention in one or more particular applications, it will be apparent to those of ordinary skill in the art that numerous modifications in form, usage and details of implementation can be made without the exercise of inventive faculty, and without departing from the principles and concepts of the invention. Accordingly, it is not intended that the invention be limited, except as by the claims set forth below.

The verbs “to comprise” and “to include” are used in this document as open limitations that neither exclude nor require the existence of also un-recited features. The features recited in depending claims are mutually freely combinable unless otherwise explicitly stated. Furthermore, it is to be understood that the use of “a” or “an”, i.e. a singular form, throughout this document does not exclude a plurality.

### ACRONYMS LIST

IBGT insulated gate bi-polar transistor
LED light emitting diode

REFERENCE SIGNS LIST

| NO. | FEATURE |
|---|---|
| 100 | heat transfer element |
| 110 | heat sink |
| 111 | body |
| 112 | dissipation section |
| 113 | heat pipe |
| 114 | counterpart surface |
| 115 | channel |
| 116 | plug |
| 117 | header |
| 118 | end |
| 119 | wall |
| 120 | coupler |
| 121 | base |
| 122 | sealing element |
| 123 | plug |
| 124 | inlet |
| 125 | first surface |
| 126 | second surface |
| 127 | coating |
| 128 | screw |
| 130 | vapor chamber |
| 200 | electric or optical component |
| 201 | substrate |
| 202 | conductor |
| 203 | electric heat source |
| 204 | lead |
| 205 | terminal |
| 206 | affixer |
| 207 | cover |

### CITATION LIST

### CN 103307579 B

### WO 2009/108192 A1

1. A heat transfer system for a heat source, the heat transfer system comprising:
a heat sink which comprises:
a header,
a body, which extends from the header, and
a dissipation section connected to the header, which dissipation section is integrated to and extends from the body and is connected to the header through the body,
a coupler which is configured to be attached to a heat source and to the header for physically connecting the heat source to a thermally transferring connection with the heat sink, which coupler defines, when attached to the heat sink, at least a part of a vapor chamber inside heat transfer system, and
at least one heat pipe which is integrated to the body and in fluid communication with the vapor chamber,
wherein the dissipation section and the body share a length in a dimension of extrusion or 3D printing.

2. The heat transfer system according to claim 1, wherein the vapor chamber is formed inside the heat sink or between the coupler and the header.

3. The heat transfer system according to claim 1, wherein the header comprises a counterpart surface, such as a recessed surface, which defines at least part of the vapor chamber.

4. The heat transfer system according to claim 1, wherein the heat sink comprises a plurality of such heat pipes integrated to the body.

5. The heat transfer system according to claim 4, wherein the vapor chamber connects at least two of the plurality of heat pipes.

6. The heat transfer system according to claim 1, wherein the coupler comprises a base for receiving and holding the heat source in a thermally conducting connection.

7. The heat transfer system according to claim 6, wherein:
the coupler comprises a sealing element formed to the base, which sealing element forms a male or female counterpart of a connection between the coupler and the header, and wherein
the header comprises a shape which is respective female or male counterpart of the connection between the coupler and the header.

8. The heat transfer system according to claim 7, wherein:
the counterpart surface is provided as a bottom of a recess in the header of the heat sink and delimited by a peripheral wall which connects an outer surface of the header to the counterpart surface, and wherein
the sealing element of the coupler is configured to engage and seal against:
the peripheral wall,
the counterpart surface, or
both the peripheral wall and the counterpart surface for closing the vapor chamber.

9. The heat transfer system according to claim 7, wherein:
a first surface of the base is configured to receive the heat source, and wherein
the sealing element extends from a second surface of the base opposing the first surface.

10. The heat transfer system according to claim 1, wherein:
the vapor chamber forms a first fluid cooling volume,
the heat pipe or heat pipes form a second fluid cooling volume, and wherein
a heat transfer fluid is provided to a combined fluid cooling volume formed by the first and second fluid cooling volumes.

11. The heat transfer system according to claim 10, wherein the heat transfer fluid is at an under pressure.

12. The heat transfer system according to claim 10, wherein the coupler comprises a selectively closable inlet which is configured to accommodate pressurizing the fluid cooling volume of the heat sink to an under pressure.

13. The heat transfer system according to claim 1, wherein the heat source is comprised by an electric or optical component.

14. The heat transfer system according to claim 1, wherein the cross-sectional area (A₂) covered by the vapor chamber is at least twice the cross-sectional area (A₁) of the heat pipe.

15. An electric or optical component comprising:
a coupler for connecting a heat source to a thermally conducting connection with a heat sink, the coupler comprising a base, which comprises a first surface for receiving the heat source in a thermally conducting connection and a second surface opposing the first surface, which coupler is configured to be attached to the heat sink so as to form a vapor chamber between the second surface of the base and the heat sink, and
a heat source, such as a semiconductor, directly or indirectly bonded or soldered to the first surface of the base of the coupler, whereby the electric or optical component, is thus formed on the coupler,
wherein
the electric or optical component is configured to be attached to the heat sink of the heat transfer system according to claim 1 directly through the coupler without an adapter,
the coupler comprises a sealing element which protrudes from the second surface of the base, and
the sealing element has a peripheral closed profile so as to define the cross-sectional shape of the fluid cooling volume in respect to a dimension.

16. The electric or optical component according to claim 15, wherein the electric component comprises:
a substrate, such as a power electronic substrate, for electric insulation between the heat source and the base, and
a terminal for a galvanic connection to an external device, which terminal is electrically connected to the heat source.

17. The electric or optical component according to claim 16,
wherein the electric component comprises a cover which covers the electric heat source, wherein the terminal is configured to extend through the cover and to provide attachment of the cover to the base.

18. The electric or optical component according to claim 15, wherein the base is made of a thermally conducting material.

19. (canceled)

20. (canceled)

21. The electric or optical component according to claim 15, wherein the first surface of the base comprises a coating which is configured to enable bonding of a heat source to the base.

22. (canceled)

23. (canceled)

24. The heat transfer system according to claim 2, wherein the header comprises a counterpart surface, such as a recessed surface, which defines at least part of the vapor chamber.
